(19) United States
(12) Patent Application Publication
(10) Pub. No.: US 2010/0283453 A1
(43) Pub. Date: Nov. 11, 2010

(54) Methods for Calibrating an Electric Meter

(75) Inventor: Rolf Wendt, Santa Rosa, CA (US)

Correspondence Address: Venture Pacific Law, PC, 5201 Great America Parkway, Suite 270, Santa Clara, CA, 95054, US

(73) Assignee: POWRtec, Campbell, CA (US)

(21) Appl. No.: 12/436,079

(22) Filed: May 5, 2009

(51) Int. Cl. G01R 11/32

(52) U.S. Cl. 324/142

(57) ABSTRACT

An energy measurement by an electric meter is determined by a method, comprising the steps of: determining a normalization constant (K) representative of a unit of measured energy for each pulse generated by said electric meter; receiving a pulse by said electric meter; and generating an energy measurement by applying said normalization constant to said received pulse.

### FIELD OF INVENTION

This invention generally relates to methods for monitoring electrical power consumption, and, more particularly, to methods for calibrating an electric meter to monitor electrical power consumption.

### BACKGROUND

Electric utility companies use electric meters to track electric energy usage by customers. These meters track the amount of power consumed at a particular location, such as at power substations, commercial businesses, or residential homes. The electric utility companies then use the information gathered by the electric meters to charge its customers for their power consumption.

Traditionally, electric meters use electromechanical means to track the amount of consumed power. For instance, an inductive spinning disk in the electric meter is commonly used for tracking the amount of power consumed. The spinning disk drives mechanical counters that track the power consumption information. However, the calibration of these conventional meters is quite labor intensive, and even when calibrated, the energy measurements may not be very accurate.

Electronic meters are newer to the market, and are replacing the older mechanical meters. The electronic meters utilize digital sampling of the voltage and current waveforms to generate power consumption information. The power consumption information is displayed on an output display device on the meter.

When a predefined amount of energy is consumed, the output display may also emit an energy measurement pulse, which is analogous to the spinning wheel of an electromechanical meter.

With respect to electric meters, it is desirable to provide methods to obtain an accurate energy measurement in real time. Generally when energy is measured, there is a device within the meter (e.g., an A/D converter), which generates a pulse that is directly related to the amount of energy the device senses. The frequency of the pulse conveys the amount of energy sensed by the device.

However, the pulse needs to be calibrated in order to return an accurate energy consumption measurement. Due to device tolerances (or deviation values), meters must be calibrated so that they remain accurate to within a few tenths of a percent. Device tolerances can be generated by resistors, capacitors, and other components in the meters. These tolerances cause inaccurate energy measurement readings.

Some of the inaccuracies that take place in traditional meters are due to the meters internal clock (e.g., a crystal) running inside the device that provides a time for the meter. Once a certain amount of time is reached, the number of received pulses for that amount of time is converted into an energy amount. The more pulses received in a defined amount of time equates to more energy relative to a lesser amount of pulses received for the same defined amount of time. For instance, if 300 pulses are accumulated in 20 seconds, then that can be converted to an equivalent energy reading of 500 watt-hours (Wh). If 200 pulses are accumulated in 20 seconds, then that can be converted to an equivalent energy reading of 333.33 Wh.

The interpolation of the internal clock by the microprocessor in the meter can be error prone due to jitter in the internal clock. Furthermore, error tolerances from the components in the meter can cause inaccurate energy consumption measurements. For instance, if a capacitor in the meter is not accurate or the temperature in the meter increases or decreases, then the frequency of the internal clock can wander or other hardware errors may occur. This leads to inaccuracies in the energy consumption measurements by the meter.

Therefore, it is desirable to provide methods for calibrating an electric meter to account for inaccurate measurements that may be generated by the components of the electric meter.

### SUMMARY OF INVENTION

An object of this invention is to provide methods for measuring energy for use by an electric meter based upon normalized energy accumulation.

Another object of this invention is to provide methods for real time energy measurements by an electric meter.

Yet another object of this invention is to provide methods for calibrating an electric meter to compensate for jitter of the internal clock of the meter and for tolerances of the components in the electric meter.

Briefly, the present invention relates to a method for determining an energy measurement by an electric meter, comprising the steps of: determining a normalization constant (K) representative of a unit of measured energy for each pulse generated by said electric meter; receiving a pulse by said electric meter; and generating an energy measurement by applying said normalization constant to said received pulse.

An advantage of this invention is that the energy measurements by an electric meter are based on normalized energy accumulation.

Another advantage of this invention is that methods for real time energy measurements by an electric meter are provided.

Yet another advantage of this invention is that methods for calibrating an electric meter to compensate for jitter of the internal clock of the electric meter and for tolerances of the components in the electric meter are provided.

### DESCRIPTION OF THE DRAWINGS

The foregoing and other objects, aspects, and advantages of the invention will be better understood from the following detailed description of the preferred embodiment of the invention when taken in conjunction with the accompanying drawings in which:

FIG. 1 illustrates a block diagram of the components for an embodiment of the present invention for measuring energy consumption.

FIG. 2 illustrates a flow chart for normalizing an energy measurement to improve the accuracy for measuring energy consumption.

FIG. 3 illustrates a flow chart for normalizing an energy measurement and displaying the normalized value of the energy measurement.

### DETAILED DESCRIPTION OF THE PREFERRED EMBODIMENTS

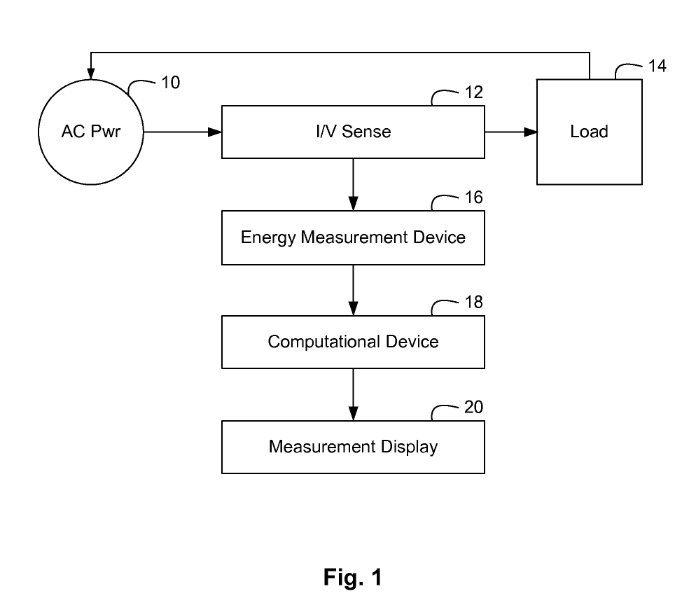

FIG. 1 illustrates a block diagram of the components for an embodiment of the present invention for measuring energy consumption by an electric meter. An alternating current (AC) power source 10 is connected to a current (I) and voltage (V) sensing circuit 12, and a load 14. The AC power 10 can be the voltage power line provided by an electric utility company. A meter can comprise of the I/V sense 12, an energy measurement device (EMD) 16, a computational device (CD) 18, and a measurement display 20. The load 14 can represent the consumption of energy by, for example, a power substation, a commercial business, a residential home, or any other consumer of energy.

The I/V sensing circuit 12 can be a resistive shunt that is placed in series with the load 14, so that all of the current to be measured will flow through the I/V sensing circuit. The voltage drop across the shunt is proportional to the current flowing through it. A volt meter connected across the shunt can be scaled to directly read the current value. The I/V sensing circuit 12 then converts the voltage and current into an energy measurement.

The I/V sensing circuit 12 outputs the sensed data to the energy measurement device 16. The EMD 16 collects the data of the current passing through the I/V sensing circuit 12, and calculates the amount of energy consumed based on this data. The EMD 16 generates one or more discrete pulses representative of the calculated amount of energy (or consumed energy). Each pulse can be representative of an approximate but consistent unit amount of energy, e.g., 1 Wh.

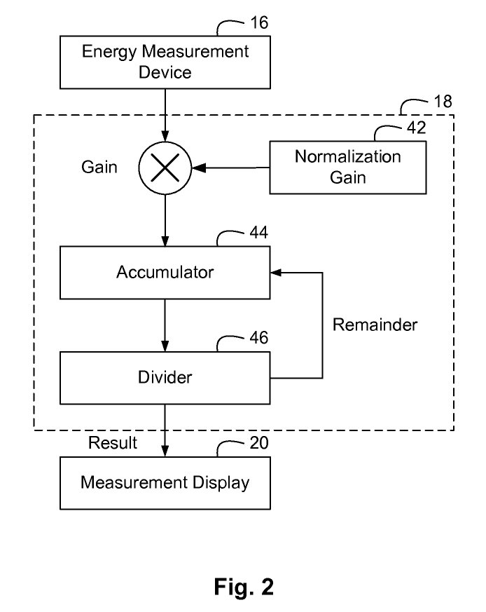

The CD 18 normalizes the unit of energy generated by the energy measurement device 16 and accumulates this normalized unit of energy in local accumulators. The CD 18 performs a conversion from the approximate but consistent energy measurement pulses emitted from the energy measurement device 16 to an accurate energy measurement. For instance, if 1 kWh is used at the load, the EMD 16 may measure 1005 kilowatt-hour (kWh) due to inaccuracies in the EMD components. The CD 18 can normalize this value, and output the normalized value that is closer to the actual energy consumed, e.g., this energy can be 1000 kWh. The algorithm used to normalize the energy values represented by pulses is illustrated in FIG. 2.

Referring to FIG. 1, a measurement display 20 provides a user readable display of the normalized amount of energy measured. The display may truncate the normalized amount of energy measured, typically in units of Wh, since typical measurement displays show kWh.

FIG. 2 illustrates a flowchart for normalizing an energy measurement to improve the accuracy in measuring energy consumption. The EMD 16 generates a pulse that represents a specific unit of energy consumed. Due to the tolerances of the components in the EMD, the energy represented by the pulse may not be accurate. The normalization gain 42 is used to calibrate the EMD 16 to accurately reflect the actual amount of consumed energy by compensating for the tolerances of the components. Thus, for every pulse generated by the EMD 16, the normalization gain 42 is multiplied to that pulse to return a compensated energy for each pulse. In essence, the normalization gain 42 serves as a gain control to remove inaccuracies of the EMD 16. The normalized pulses are accumulated to obtain a normalized energy measurement.

The compensated energy value is outputted to an accumulator 44 which keeps track of the consumed energy and stores the total amount of energy sensed by the EMD 16. The accumulator 44 typically can have a high level of accuracy of up to a Wh. Therefore, a divider 46 may be used to truncate the accuracy to a kWh since a measurement display 20 typically only displays energy readings down to a kWh.

Due to tolerances in the components of the EMD 16, the normalization constant calibrates the energy measurement to compensate for the tolerances in the components. For instance, if a generated pulse from the EMD 16 represents 1 Wh, it may not be the actual amount of energy consumed due to the tolerances in the components of the metering device. Since the EMD 16 is not calibrated to adjust for these tolerances, the actual amount of energy consumed can vary. For instance, the actual amount of energy consumed per pulse may be 0.90 of a Wh. The normalization gain can adjust the EMD's 16 pulses to reflect this difference by multiplying the EMD energy value on a per pulse basis by a normalization gain, e.g., of 0.90.

The accumulator 44 can accumulate the normalized energy pulses by adding the normalized value each time a pulse is received from the EMD 16, and store a total amount of normalized energy measured by the EMD 16. For instance, if the normalization constant is 0.9, the accumulator will increase by 0.9 for each and every pulse received from the EMD 16. The divider 46 decreases this precision from a Wh to a kWh since normally Wh precision is not needed for the display. Any remainder value of energy is stored back in the accumulator 44.

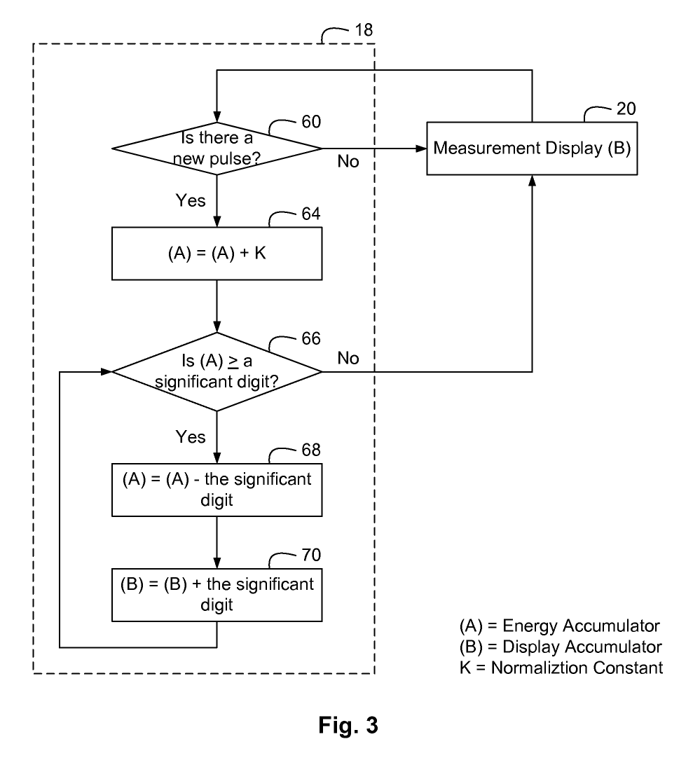

FIG. 3 illustrates a flow chart for normalizing an energy measurement and displaying the normalized value of the energy measurement. If there is a new pulse 60 generated by the EMD 16, then a unit of energy, K, is added to a total energy accumulator value, A. The unit of energy, K, is the calibrated amount of energy for each pulse. K represents the normalized value of each pulse. For instance, assume the calibrated meter senses 0.8 Wh per pulse, then k=0.8 Wh. If a new pulse is not detected 60, then the measurement display 20 displays a display accumulator value, B.

If the energy accumulator value, A, is greater than or equal to one 66, then subtract one from the energy accumulator value, A, 68 and add one to the display accumulator value, B, 70. This is analogous to a counter overflow. The overflow is what is relevant in the display of the energy usage. The remainder is preserved for further energy measurement assuring a precise energy measurement over time. Repeat these steps until the energy accumulator value, A, is less than one. This accommodates extremely large inaccuracies in the EMD 16. If the energy accumulator value, A, is less than 1, then display the display accumulator value, B, 20.

The normalization constant calibrates the EMD to measure an accurate amount of energy represented by each generated pulse. Tolerances due to temperature variation can be avoided in the metering device by selecting components that are stable over a given range of temperatures. Furthermore, the normalization constant can be determined such that the measured energy can be calibrated to eliminate the inaccuracy due to the tolerances (and deviations) of the components in the meter. The electric meter can have a plurality of components, wherein each component and in combination with each other can contribute to inaccurate measurements. The normalization constant is provided to account for such inaccurate measurements.

In an embodiment of the invention, the normalization constant can be derived by applying a known amount of energy across the IN sense to compare the measured amount of energy sensed and the known amount of energy consumed. The number of pulses generated for that known amount of energy can be stored and tracked. The known amount of energy can then be divided by the number of received pulses to return the normalized amount of consumed unit energy per pulse.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A method for determining an energy measurement by an electric meter, comprising the steps of:
determining a normalization constant (K) representative of a unit of measured energy for each pulse generated by said electric meter;
receiving a pulse by said electric meter; and
generating an energy measurement by applying said normalization constant to said received pulse.

2. The method of claim 1 wherein the electric meter has an I/V sense circuit and the I/V sense circuit has a tolerance, and the normalization constant accounts for such tolerance.

3. The method of claim 1 wherein in the determining step, the normalization constant, K, is determined as a function of a known amount of energy, a known load, and the amount of energy sensed across the known load giving the known amount of energy, and the number of received pulses corresponding to the amount of energy sensed across the known load giving the known amount of energy.

4. The method of claim 1 wherein the generating step further comprises the substeps of:
accumulating K units of energy for each received pulse;
cumulating the accumulated units of energy to a significant digit; and
displaying the cumulated energy units.

5. The method of claim 1 wherein the generating step further comprises the substeps of:
accumulating K units of energy for each received pulse;
while the accumulated units of energy is greater than or equal to a significant digit, reducing the accumulated units of energy by the significant digit and increasing a displayed accumulated energy units by the significant digit; and
displaying the displayed accumulated energy units.

6. A method for determining an energy measurement by an electric meter, comprising the steps of:
determining a normalization constant (K) representative of a unit of measured energy for each pulse generated by said electric meter;
receiving a pulse by said electric meter; and
generating an energy measurement by applying said normalization constant to said received pulse,
wherein the electric meter has an I/V sense circuit and the I/V sense circuit has a tolerance, and the normalization constant accounts for such tolerance.

7. The method of claim 6 wherein in the determining step, the normalization constant, K, is determined as a function of a known amount of energy, a known load, and the amount of energy sensed across the known load giving the known amount of energy, and the number of received pulses corresponding to the amount of energy sensed across the known load giving the known amount of energy.

8. The method of claim 6 wherein the generating step further comprises the substeps of:
accumulating K units of energy for each received pulse;
cumulating the accumulated units of energy to a significant digit; and
displaying the cumulated energy units.

9. The method of claim 7 wherein the generating step further comprises the substeps of:
accumulating K units of energy for each received pulse;
cumulating the accumulated units of energy to a significant digit; and
displaying the cumulated energy units.

10. The method of claim 6 wherein the generating step further comprises the substeps of:
accumulating K units of energy for each received pulse;
while the accumulated units of energy is greater than or equal to a significant digit, reducing the accumulated units of energy by the significant digit and increasing a displayed accumulated energy units by the significant digit; and
displaying the displayed accumulated energy units.

11. The method of claim 7 wherein the generating step further comprises the substeps of:
accumulating K units of energy for each received pulse;
while the accumulated units of energy is greater than or equal to a significant digit, reducing the accumulated units of energy by the significant digit and increasing a displayed accumulated energy units by the significant digit; and
displaying the displayed accumulated energy units.

12. A method for determining an energy measurement by an electric meter, comprising the steps of:
determining a normalization constant (K) representative of a unit of measured energy for each pulse generated by said electric meter, wherein the normalization constant, K, is determined as a function of a known amount of energy, a known load, and the amount of energy sensed across the known load giving the known amount of energy, and the number of received pulses corresponding to the amount of energy sensed across the known load giving the known amount of energy;
receiving a pulse by said electric meter; and
generating an energy measurement by applying said normalization constant to said received pulse, comprising the substeps of:
accumulating K units of energy for each received pulse;
while the accumulated units of energy is greater than or equal to a significant digit, reducing the accumulated units of energy by the significant digit and increasing a displayed accumulated energy units by the significant digit; and
displaying the displayed accumulated energy units,
wherein the electric meter has an I/V sense circuit and the I/V sense circuit has a tolerance, and the normalization constant accounts for such tolerance.
